(19) United States
(12) Patent Application Publication
(10) Pub. No.: US 2010/0188078 A1
(43) Pub. Date: Jul. 29, 2010

(54) MAGNETIC SENSOR WITH CONCENTRATOR FOR INCREASED SENSING RANGE

(76) Inventors: Andrea Foletto, Annecy (FR); Andreas P. Friedrich, Metz-Tessy (FR); William P. Taylor, Amherst, NH (US)

Correspondence Address: DALY, CROWLEY, MOFFORD & DURKEE, LLP, SUITE 301A, 354A TURNPIKE STREET, CANTON, MA, 02021-2714, US

(21) Appl. No.: 12/360,889

(22) Filed: Jan. 28, 2009

(51) Int. Cl. G01R 33/02; G01R 33/07; G01R 33/09

(52) U.S. Cl. 324/251; 324/244; 324/252

(57) ABSTRACT

A sensor that includes a magnetic flux concentrator is presented. The sensor includes a sensor integrated circuit with a structure that includes a magnetic field sensor to sense a magnetic field generated by an external magnetic flux source comprising a magnetic article. The stricture has a first surface to face the external magnetic flux source and an opposing second surface. The sensor integrated circuit also includes a lead frame connected to the structure and having a base portion with a first base portion surface to support the stricture and an opposing second base portion surface. Also provided in the sensor is a magnetic flux concentrator to concentrate magnetic flux of the magnetic field. The magnetic flux concentrator can be disposed proximate to the second base portion surface such that the structure and lead frame base portion are located between the magnetic flux concentrator and the external magnetic flux source when the sensor integrated circuit is positioned relative to the external magnetic flux source.

### CROSS-REFERENCE TO RELATED APPLICATIONS

Not applicable.

### STATEMENT REGARDING FEDERALLY SPONSORED RESEARCH

Not applicable.

### FIELD OF THE INVENTION

This invention relates generally to magnetic field sensors and more particularly, to magnetic field sensors used in conjunction with magnetic flux concentrators.

### BACKGROUND OF THE INVENTION

The use of magnetic flux concentrators in magnetic field sensing applications is well known. Applications include magnetic field sensors that detect movement, as well as magnetic field sensors that can measure current (“current sensors”).

In some prior sensors with back-biasing permanent magnets, for example, a magnetic flux concentrator is provided between the back-biasing magnet and a sensor integrated circuit (IC). The sensor IC contains at least one active sensing element (such as a Hall-effect element). This type of arrangement is useful in applications like gear tooth sensing applications that involve a ferromagnetic object (e.g., a toothed wheel) as a target. Because the back-biasing permanent magnet generates a magnetic field for that target, the magnetic flux concentrator acts to strengthen the magnetic force between the target and magnet. It may also serve to flatten any “peaks” in the magnetic field or magnetic flux density across the face of the magnet.

Conventional current sensors include implementations in which the magnetic flux concentrator is made a part of the sensor IC, and is shaped and positioned (relative to the sensing device) to guide the magnetic flux in a particular direction. For instance, some current sensing applications require a particular type of conductor shape or location, e.g., the conductor may be located adjacent to the sensor IC, or use a specially shaped sensing device. Thus, the magnetic flux concentrator is needed to direct (or redirect) the flux so that it can be measured effectively by the sensing device. Designs include the integration of a magnetic flux concentrator on the sensor die. This level of integration may require additional wafer fabrication processing or post-processing, which can add cost and complexity to the sensor IC manufacture.

### SUMMARY OF THE INVENTION

In general, in one aspect, the invention is directed to a sensor integrated circuit (IC). The sensor IC includes a structure comprising a magnetic field sensor to sense a magnetic field generated by an external flux source comprising a magnetic article. The structure has a first surface to face the external flux source and an opposing second surface. The sensor IC further includes a lead frame connected to the structure and having a base portion with a first base portion surface to support the structure and an opposing second base portion surface. Also included in the sensor IC is a magnetic flux concentrator to concentrate magnetic flux of the magnetic field. The magnetic flux concentrator comprises a layer of soft magnetic material that is disposed proximate to the second base portion surface such that the structure and lead frame base portion are located between the magnetic flux concentrator and the magnetic flux source when the sensor IC is positioned relative to the external magnetic flux source.

In another aspect, the invention is directed to a sensor assembly. The sensor assembly includes a magnetic field sensor IC to sense a magnetic field generated by an external magnetic flux source comprising a magnetic article. The magnetic field sensor IC includes a package that encapsulates a magnetic field sensor. The package has a first surface to face the magnetic flux source when the magnetic field sensor integrated circuit is positioned relative to the external magnetic flux source and a second opposing surface. The sensor assembly further includes a magnetic flux concentrator, comprising a soft magnetic material, affixed to the second opposing surface of the package and a housing in which the magnetic field sensor IC and the magnetic flux concentrator are mounted.

Particular implementations of the invention may provide one or more of the following advantages. Unlike the magnetic flux concentrators of prior solutions, this magnetic flux concentrator can be a stand-alone structure of an adequate geometry that can be placed in close proximity to the magnetic field sensor, either inside or outside of the magnetic field sensor IC package. It can be placed behind the magnetic field sensor IC in an arrangement that does not include a back biasing magnet, thus optimizing the magnetic flux concentration solution for applications with targets that incorporate a magnetic flux source. Also, the use of a magnetic flux concentrator in such configurations causes an increase in magnetic flux concentration, which in turn increases the maximal sensing range over which the magnetic field sensor IC can operate. A target can therefore be placed at a greater distance from the magnetic field sensor IC than would otherwise be possible.

### BRIEF DESCRIPTION OF THE DRAWINGS

The foregoing features of the invention, as well as the invention itself, may be more fully understood from the following detailed description of the drawings, in which:

FIGS. 1A-1B show an exemplary magnetic field sensor application that includes a magnetic flux source and a magnetic field sensor integrated circuit (IC) that uses an external magnetic flux concentrator (FIG. 1A) or an internal magnetic flux concentrator (FIG. 1B);

FIG. 2 is a partial exploded perspective view of an exemplary magnetic field sensor sub-assembly, specifically the magnetic field sensor IC and external magnetic flux concentrator housed with the magnetic field sensor IC in the sub-assembly;

FIGS. 3A-3D are cross-sectional side views of an exemplary magnetic field sensor IC with external magnetic flux concentrator in a sub-assembly (FIG. 3A) or internal magnetic flux concentrator (FIGS. 3B-3D);

FIG. 4 is a perspective view of a typical sensor portion of the magnetic field sensor IC; and

FIG. 5 is a graphical depiction of the relationship between air gap and magnetic field strength for a magnetic field sensor with magnetic flux concentrator and without magnetic flux concentrator.

### DETAILED DESCRIPTION

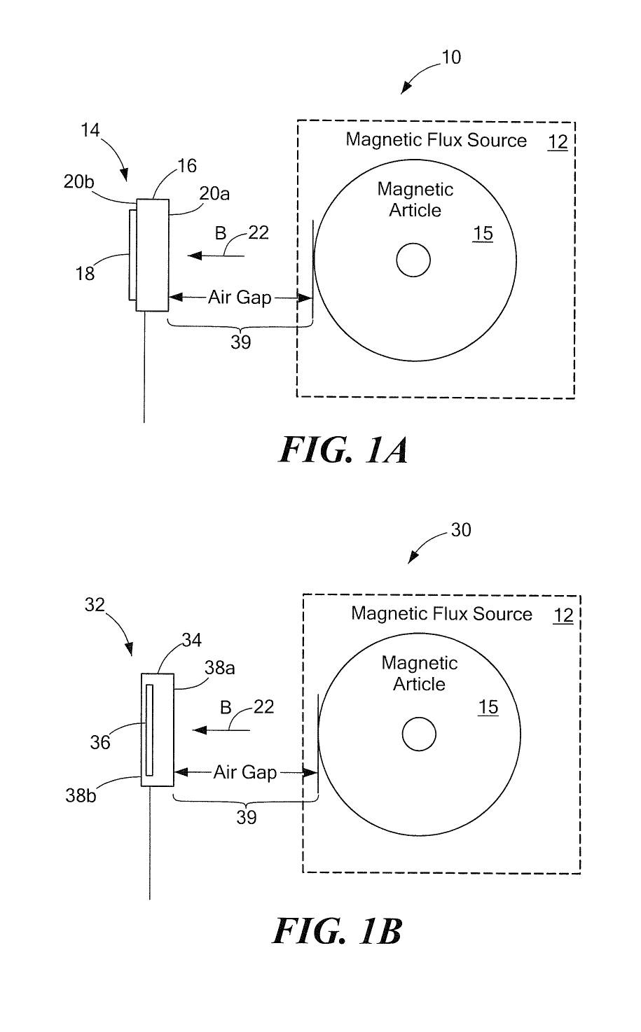

FIGS. 1A-1B illustrate a magnetic field sensing application that features a magnetic field sensor configured to use a magnetic flux concentrator to increase its sensing range with respect to a magnetic flux source. In one exemplary embodiment, as shown in FIG. 1A, a magnetic field sensing application 10 includes a magnetic flux (or field) source 12 and a sensor 14. The magnetic flux source 12 may be (or may be implemented to include) a magnetic article 15 such as a ring magnet, as shown. The sensor 14 includes a magnetic field sensing device in the form of a magnetic field sensor integrated circuit (“IC”) 16. Also included in the sensor 14 is a magnetic flux concentrator 18 that is disposed proximate to the magnetic field sensor IC 16. The magnetic flux concentrator 18 is externally coupled to or with the magnetic field sensor IC package 16, possibly within a housing, e.g., a plastic canister, of a package sub-assembly (not shown). In one implementation, the magnetic flux concentrator 18 may be mounted on or otherwise affixed to the magnetic field sensor IC 16. As indicated in the figure, the magnetic field sensor IC 16 has a first surface 20a and an opposing second surface 20b. The first surface 20a faces the magnetic flux source 12. The sensing device of an internal magnetic field sensor detects a magnetic field having a magnetic flux density “B” (indicated by arrow 22) generated by the magnetic flux source 12. The direction of the magnetic field is perpendicular to the first surface 20a. The magnetic flux concentrator 18 is disposed proximate to the second surface 20b. It can be said to be positioned behind or in back of the magnetic field sensor IC 16 when the first surface 20a is taken as the front of the package.

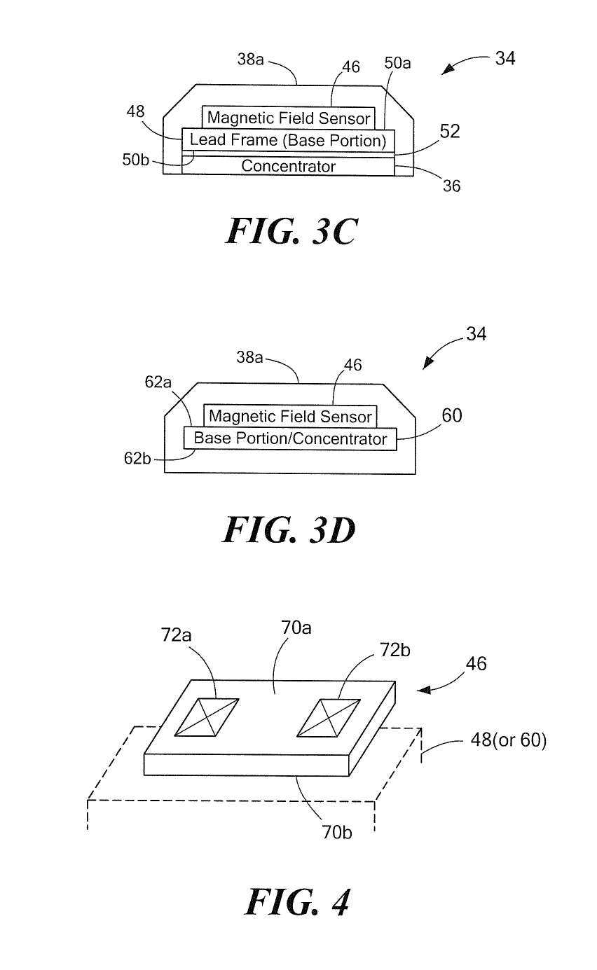

In an alternative embodiment, and referring to an application 30 shown in FIG. 1B, the sensor, shown here as sensor 32, can be implemented with a magnetic field sensor IC 34 having an internal magnetic flux concentrator 36. The magnetic flux concentrator 36 may be coupled to (or, alternatively, integrated with) an internal magnetic field sensor (that is, a magnetic field sensor portion of the magnetic field sensor IC 34), as will be described later with reference to FIGS. 3B-3D. The magnetic field sensor IC 34 has a first surface 38a (which faces the magnetic flux source 12) and an opposing second surface 38b.

The magnetic flux concentrator 18, 36 acts to amplify and/or concentrate the magnetic flux of the magnetic field. Simply put, it “closes” the magnetic circuit generated by the magnetic flux source 12. Stated another way, the magnetic flux concentrator 18, 36 reduces the reluctance of the magnetic circuit, thereby increasing the magnetic flux density observed by the magnetic field sensor IC.

The sensor 14, 32 may be movable or fixed relative to the magnetic flux source 12. In the application, it is positioned in proximity to the magnetic flux source 12. The smallest distance or gap between the sensor IC face (shown in FIG. 1A as surface 20a or FIG. 1B as surface 38a) and the active face of the magnetic flux source 12 defines and is referred to as the air gap or sensing distance. In FIGS. 1A-1B, an air gap 39 between surfaces 20a, 38a and an active face of the magnetic article 15 is shown. The air gap is specified by the application based on the needs of the application as well as characteristics of various components, including the magnetic flux source and sensor. The air gap may be fixed or variable (for example, based on movement and/or shape of at least one of the magnetic flux source and sensor IC) for a given application. The air gap can vary from application to application as well.

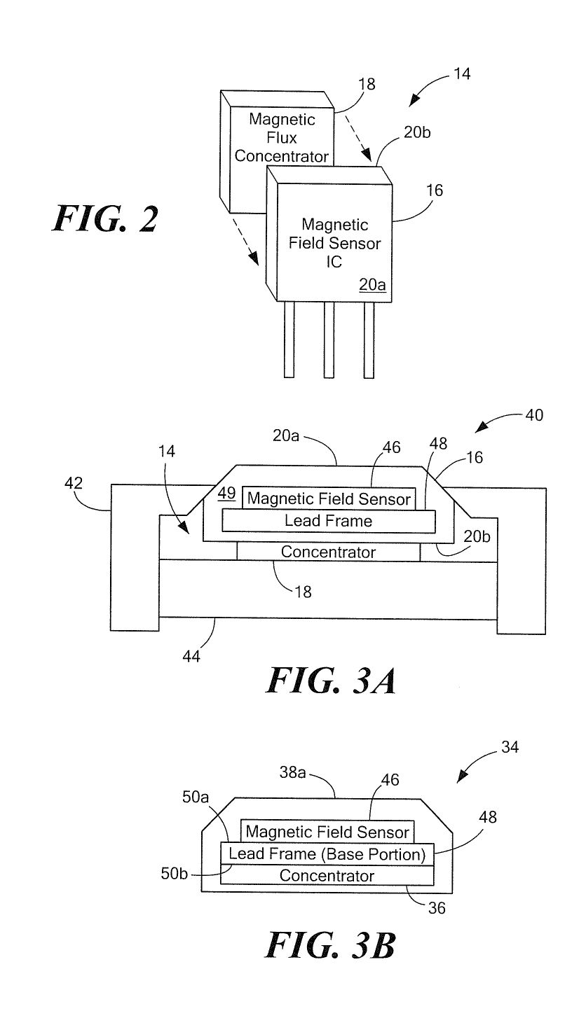

FIG. 2 shows a perspective view of the sensor 14 (from FIG. 1A). It can be seen that the magnetic flux concentrator 18 is positioned “behind” the magnetic field sensor IC 16. Again, as noted earlier, the magnetic flux concentrator 18 may be placed in close proximity to or on the second surface 20b. It may be attached to the second surface 20b in some manner, for example, through the use of an adhesive material, such as an epoxy adhesive or adhesive tape. Consequently, and referring to FIGS. 1A and 2, in the sensing application 10, the magnetic field sensor IC 16 will be located between the magnetic flux concentrator 18 and the magnetic flux source 12. The magnetic flux concentrator 18 can have various shapes based on design requirements. It need not have the square shape depicted in FIG. 2.

Exemplary construction details are shown in the cross-sectional side views of FIGS. 3A-3D. FIG. 3A corresponds to the sensor/concentrator arrangement depicted in FIG. 1A and FIGS. 3B-3D correspond to the sensor/concentrator arrangement depicted in FIG. 1B, respectively.

Referring first to FIG. 3A, a package sub-assembly (or sensor assembly) 40 includes a housing formed by a first member 42 and second member 44. Members 42 and 44 serve to encase or house the sensor 14 (from FIG. 1A), which includes the concentrator 18 and magnetic field sensor IC 16. Other types of housing, for example, a one-piece housing, could be used as well. A one-piece housing, if used, could be ultrasonically welded to the sensor 14. A single-shot overmolding process could also be used. It can be seen from the view shown in FIG. 3A that the magnetic field sensor IC 16 contains a structure 46 that implements the functionality of a magnetic field sensor. This “structure” may take the form of a single die, two or more die coupled to a common substrate, or other arrangements. The magnetic field sensor or structure 46 is connected to a lead frame 48. The portion of the lead frame that is shown in the figure as lead frame 48 is a base portion, sometimes referred to as a “base plate.” The lead frame 48 can be formed, for example, from a material having a relatively low magnetic permeability, such as copper. The lead frame 48 and magnetic field sensor 46 are encapsulated by a package body 49.

FIG. 3B shows a cross-sectional side view of the magnetic field sensor IC 34 (from FIG. 1B). Like the sensor IC 16, the magnetic field sensor IC 34 contains a magnetic field sensor and a lead frame, shown again as magnetic field sensor 46 and lead frame 48. In this construction, the flux concentration is provided within the magnetic field sensor IC 34. Magnetic flux concentrator 36 is disposed proximate to the lead frame 48. The lead frame or lead frame base portion 48 has a first base portion surface 50a and a second base portion surface 50b. In one exemplary implementation, the magnetic flux concentrator 36 is mounted to (for example, with an adhesive material) or formed on the under side of the lead frame base portion 48, that is, the second base portion surface 50b, whereas the magnetic field sensor 46 is coupled to and supported on the first base portion surface 50a (or top side) of the lead frame base portion 48. The attachment of magnetic field sensor 46 to the first base portion surface 50a could also be made through the use of an adhesive material, such as an epoxy adhesive. The magnetic flux concentrator 36 may be formed on the second base portion surface 50b by using an electroplating process. Other suitable processes may be used as well. FIG. 3C shows an exemplary alternative embodiment to that shown in FIG. 3B. As shown in FIG. 3C, there is disposed between the lead frame base portion 48 and the concentrator 36 a non-conductive layer 52, for example, a non-conductive epoxy layer. The use of such a layer allows the size of the concentrator 36 to exceed that of the lead frame base portion 48, as the non-conductive epoxy layer 52 will insulate the lead frame leads or pins (not shown) from the base portion (and thus prevent lead shorting). If planarity of the magnetic flux concentrator 36 is important, then an epoxy containing spacers (e.g., glass beads) may be used. The spacers would provide a mechanical stand-off during attachment as the magnetic flux concentrator is pressed into the epoxy. The epoxy could be replaced by other polymer materials, for example, silicone.

In yet another exemplary embodiment, and referring now to FIG. 3D, the lead frame base portion may be constructed in such a fashion that it can serve as magnetic flux concentrator 36. Such an implementation of the magnetic flux concentrator 36 is shown in the figure as a combined base portion/concentrator 60. Suitable processing techniques for providing magnetic flux concentrator 36 as the combined base portion/concentrator 60 may include, for example, techniques like those described in U.S. patent application Ser. No. 11/051,124, entitled “Integrated Sensor Having a Magnetic Flux Concentrator,” filed Feb. 4, 2005 with inventors William P. Taylor, Richard Dickinson and Michael C. Doogue, and assigned to Allegro Microsystems, Inc., the assignee of the subject application. The base portion/concentrator has a first surface 62a, which is coupled to the magnetic field sensor 46, and a second surface 62b.

FIG. 4 shows some details of the magnetic field sensor 46, according to one exemplary embodiment. The magnetic field sensor 46 has a first surface 70a, which would face towards the external flux source when the sensor IC 34 is positioned for sensing in an application environment, and an opposing second surface 70b. Formed in the active sensing surface 70a is a magnetic field sensing device or element that provides a magnetic field signal, for example, a voltage signal, proportional to the sensed magnetic field. It includes at least one active (that is, magnetically responsive) element for sensing the strength of the magnetic field. In the figure, the sensing device is shown to include a Hall-effect device made up of a pair of Hall-effect elements 72a, 72b.

Thus, the sensing device may include a single element or, alternatively, may include two or more elements arranged in various configurations, e.g., a half bridge or full (Wheatstone) bridge. The sensor IC can be any type of sensor and is therefore not limited to the Hall-effect sensor IC shown in FIGS. 3A-3D and FIG. 4. Thus, the element or elements of the sensing device may take a form other than that of a Hall-effect element, such as a magnetoresistance (MR) element. An MR element may be made from any type of MR device, including, but not limited to: an anisotropic magnetoresistance (AMR) device; a giant magnetoresistance (GMR) device; a tunneling magnetoresistance (TMR) device; and a device made of a semiconductor material other than Silicon, such as Gallium-Arsenide (GaAs) or an Indium compound, e.g., Indium-Antimonide (InSb).

Other aspects of the magnetic field sensor 46, not shown, may be implemented according to known techniques and designs. It will be understood that the sensing device (illustrated as Hall-effect elements 72a, 72b) will be connected to other circuitry (that can be referred to generally as an “interface circuit”), which may contain various circuits that operate collectively to generate a sensor output from the magnetic field signal. The sensing device and interface circuit can be provided on the same die or on separate dies.

The magnetic flux produced by a magnetic flux source rapidly decreases as the distance between the magnetic flux source and the magnetic field sensor IC is increased. Referring now to FIGS. 1A-1B in conjunction with FIGS. 3A-3D and FIG. 4, each configuration (internal concentrator and external concentrator) provides a sensor IC/concentrator arrangement that allows the magnetic flux source 12 to be positioned close to or at some distance from the sensor 14, 32. In either configuration, the magnetic flux concentrator 18, 36 is placed in close proximity to the magnetic field sensor 46 to focus the lines of magnetic flux on the internal sensing element (such as Hall elements 72a, 72b). The result of such an arrangement is an increase in the maximal operating distance (i.e., air gap) between the magnetic flux source 12 and the magnetic field sensor 46, which allows for greater flexibility in the design and implementation of magnetic circuits in magnetic field sensing applications, for example, automotive and industrial applications. With the larger air gaps it is possible to achieve higher manufacturing tolerances and clearances, as well as increased resistance to vibration (without sacrificing sensing accuracy).

Referring back to FIGS. 1A-1B, the magnetic flux source 12 may be any device or structure that produces magnetic flux in a given magnetic field sensing application. It may be implemented as a magnetic article made of a hard ferromagnetic material to include a permanent magnet, such as a ring magnet (as illustrated in FIGS. 1A-1B) or two-pole magnet. That magnet may be coupled to or mounted within a “target” device, i.e., an object to be sensed, such as a moving or rotating device, e.g., a gear or rotor. It may be part of a magnet/coil assembly, for example, the type used in linear motor control and voice coil actuator applications. Other possible magnetic flux sources can include electromagnets (e.g., current carrying wire conductors and coils), such as those used in current sensing applications, and other current carrying devices that produce magnetic fields.

In the figures, the sensor IC package is depicted as a single in-line package (“SIP”), a package type commonly used for magnetic field sensors, in particular, Hall-effect sensors; however, other suitable packaging options may be used. The sensor IC package body may be made of a nonmagnetic material such as plastic (e.g., thermoset plastic) or other appropriate package body material.

Soft magnetic material suitable to concentrate flux, if of appropriate thickness, could serve as the magnetic flux concentrator 18, 36. Various materials, including (but not limited to) ferrite, steel, iron compounds, Peimalloy or other soft magnetic materials, could be used. The magnetic flux concentrator would provide an increased magnetic field proximate the magnetic field sensor 46, resulting in an increased sensitivity of the sensing device to a magnetic field.

In some embodiments, the magnetic flux concentrator may be formed using a thin film deposition of soft magnetic material during the construction of the sensor IC. It may also be formed by, for example, an electroplating operation using a thin film deposition to define the electroplated area. Alternatively, it may be formed separately, and then affixed to the back of the lead frame (as discussed above) or the sensor IC package.

In the embodiment depicted in FIG. 3D, the entire lead frame may be made of a soft magnetic material, for example, Kovar. Such a construction would eliminate some steps or materials that would be required if the base portion (concentrator) 60 and the rest of the lead frame were not made from the same material. It will be understood, however, that there are some design considerations that must be taken into account to ensure that the choice of material for the pins does not adversely affect device performance in the end application.

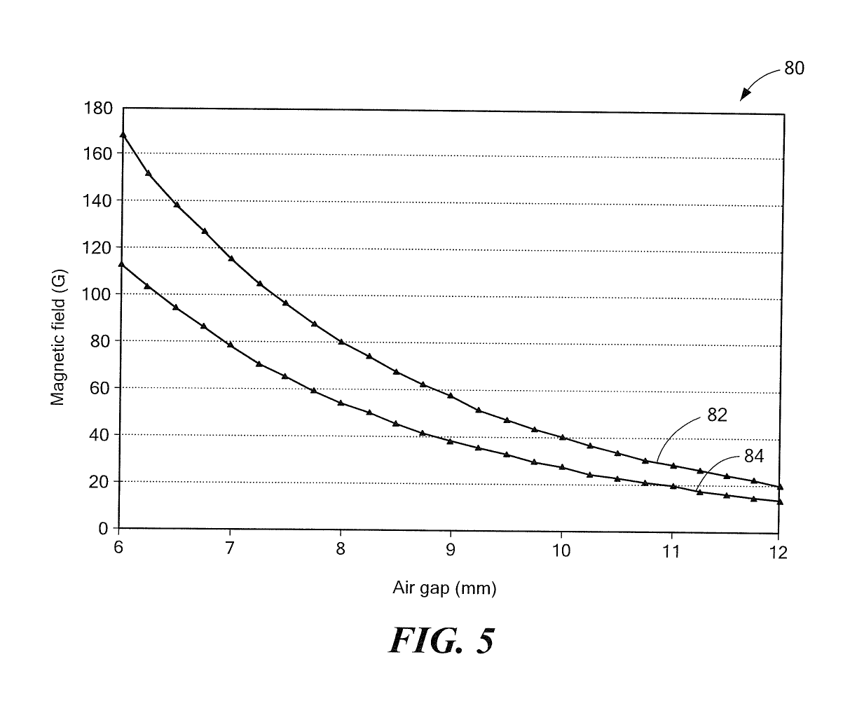

FIG. 5 shows a graph 80 of magnetic field strength versus air gap. It compares a magnetic field sensor with a magnetic flux concentrator (curve 82) and without magnetic flux concentrator (curve 84) in the presence of a magnetic field generated by an external magnetic flux source. Specifically, the results were produced for an arrangement in which a magnetic flux concentrator was positioned in back of a sensor IC (like sensor IC 16), which was placed in the proximity of a commercially available ring magnet. The results indicate that the peak-to-peak flux increased by a factor of about 1.5 for the magnetic field sensor with the magnetic flux concentrator relative to the magnetic field sensor without concentrator. A maximum permissible air gap improvement of more than 1 mm was achieved.

The characteristics of the magnetic flux concentrator, in particular, the material composition and its associated magnetic properties, as well as the shape and thickness, will determine the concentration effect provided by the concentrator. How much of a concentration effect is needed will depend on the type of sensing device that is used, e.g., in the case of Hall-effect sensors, whether the sensor has a single-element design, differential dual-element design or more complex direction detection scheme with more than two Hall-effect elements, as well as the air gap requirements of the application. Although the type of concentrator solution described herein is particularly well-suited to automotive engine management applications, for example, transmission, crank shaft and cam shaft applications, it may be used in non-automotive applications as well. It may be particularly useful in applications that may require a relatively large air gap.

All references cited herein are hereby incorporated herein by reference in their entirety.

Having described preferred embodiments of the invention, it will now become apparent to one of ordinary skill in the art that other embodiments incorporating their concepts may be used. It is felt therefore that these embodiments should not be limited to disclosed embodiments, but rather should be limited only by the spirit and scope of the appended claims.

What is claimed is:

1. A sensor integrated circuit comprising:
a structure comprising a magnetic field sensor to sense a magnetic field generated by an external magnetic flux source comprising a magnetic article, the structure having a first surface to face the external magnetic flux source and an opposing second surface;
a lead frame connected to the structure and having a base portion with a first base portion surface to support the structure and an opposing second base portion surface; and
a magnetic flux concentrator to concentrate magnetic flux of the magnetic field, the magnetic flux concentrator comprising a layer of soft magnetic material disposed proximate to the second base portion surface such that the structure and lead frame base portion are located between the magnetic flux concentrator and the external magnetic flux source when the sensor integrated circuit is positioned relative to the external magnetic flux source.

2. The sensor integrated circuit of claim 1 wherein the magnet flux concentrator is coupled to the second base portion surface.

3. The sensor integrated circuit of claim 2 wherein the magnetic flux concentrator is disposed on the second base portion surface.

4. The sensor integrated circuit of claim 3 wherein the soft magnetic material layer comprises a layer that has been electroplated onto the second base portion surface.

5. The sensor integrated circuit of claim 1 further comprising a non-conductive layer disposed between the second base portion surface and the magnetic flux concentrator.

6. The sensor integrated circuit of claim 1 wherein the magnetic field sensor comprises at least one active element to sense a magnetic field and the at least one active element element is a selected one of a Hall-effect element or a magnetoresistive (MR) element.

7. The sensor integrated circuit of claim 1 wherein the magnetic field sensor is operable to sense a magnetic field when the magnetic field sensor integrated circuit and the external magnetic flux source are spaced apart by a variable air gap.

8. A sensor integrated circuit comprising:
a structure comprising a magnetic field sensor to sense a magnetic field generated by an external magnetic flux source comprising a magnetic article, the structure having a first surface to face the external magnetic flux source and an opposing second surface; and
a lead frame, connected to the opposing second surface of the structure, having a base portion to support the structure, the base portion comprising a magnetic flux concentrator that comprises a soft magnetic material.

9. The sensor integrated circuit of claim 8 wherein the magnetic field sensor comprises at least one active element to sense a magnetic field and the at least one active element element is a selected one of a Hall-effect element or a magnetoresistive (MR) element.

10. The sensor integrated circuit of claim 8 wherein the magnetic field sensor is operable to sense a magnetic field when the magnetic field sensor integrated circuit and the external magnetic flux source are spaced apart by a variable air gap.

11. The sensor assembly comprising:
a magnetic field sensor integrated circuit to sense a magnetic field generated by an external magnetic flux source comprising a magnetic article, the magnetic field sensor integrated circuit comprising a package that encapsulates a magnetic field sensor, the package having a first surface to face the external magnetic flux source when the magnetic field sensor integrated circuit is positioned relative to the external magnetic flux source and a second opposing surface;
a magnetic flux concentrator, comprising a soft magnetic material, affixed to the second opposing surface of the package; and
a housing in which the magnetic field sensor integrated circuit and the magnetic flux concentrator are mounted.

12. The sensor assembly of claim 11 wherein the magnetic flux concentrator comprises a structure formed by an electroplating operation prior to being affixed to the second opposing surface.

13. The sensor assembly of claim 11 wherein the magnetic field sensor comprises at least one active element to sense a magnetic field and the at least one active element element is a selected one of a Hall-effect element or a magnetoresistive (MR) element.

14. The sensor assembly of claim 11 wherein the magnetic field sensor is operable to sense a magnetic field when the magnetic field sensor integrated circuit and the external magnetic flux source are spaced apart by a variable air gap.

15. A system comprising:
a magnetic flux source comprising a magnetic article; and
a sensor integrated circuit comprising:
a structure comprising a magnetic field sensor to sense a magnetic field generated by the magnetic flux source, the structure having a first surface to face the magnetic flux source and an opposing second surface;
a lead frame connected to the structure and having a base portion with a first base portion surface to support the structure and an opposing second base portion surface; and
a magnetic flux concentrator to concentrate magnetic flux of the magnetic field, the magnetic flux concentrator comprising a layer of soft magnetic material disposed proximate to the second base portion surface such that the structure and lead frame base portion are located between the magnetic flux concentrator and the magnetic flux source when the sensor integrated circuit is positioned relative to the magnetic flux source.

16. The system of claim 15 wherein the magnetic flux source comprises a permanent magnet.

17. The system of claim 16 wherein the permanent magnet comprises a ring magnet.

18. The system of claim 15 wherein the magnetic flux source comprises an electromagnet.
